(19) United States
(12) Patent Application Publication
(10) Pub. No.: US 2025/0393314 A1
(43) Pub. Date: Dec. 25, 2025

(54) VERTICAL SILICON CONTROLLED RECTIFIERS

(71) Applicant: International Business Machines Corporation, Armonk, NY (US)

(72) Inventors: Anindya Nath, Watervliet, NY (US); Ruilong Xie, Niskayuna, NY (US); Robert Gauthier, Williston, VT (US); Masoud Zabihi, Schenectady, NY (US); Anthony I-Chih Chou, Guilderland, NY (US)

(21) Appl. No.: 18/751,537

(22) Filed: Jun. 24, 2024

(51) Int. Cl. H01L 27/02

(52) U.S. Cl. CPC H10D 89/713

(57) ABSTRACT

A semiconductor structure includes a first set of one or more interconnects at a first side of the semiconductor structure, a second set of one or more interconnects at a second side of the semiconductor structure opposite the first side of the semiconductor structure, and a vertical silicon controlled rectifier having an anode junction, a cathode junction, a first gate junction and a second gate junction. The anode junction and the first gate junction of the vertical silicon controlled rectifier are wired to the first set of one or more interconnects at the first side of the semiconductor structure. The cathode junction of the vertical silicon controlled rectifier is wired to the second set of one or more interconnects at the second side of the semiconductor structure.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

A field-effect transistor (FET) is a three-terminal device having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the area of FETs. One technique is through the use of fin-shaped channels in FinFET devices. Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures the gate can more effectively control the channel, as the gate extends over more than one side or surface of the channel. In FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheets may be two-dimensional nanostructures, such as sheets having a thickness range on the order of 1 to 100 nanometers (nm). Nanosheets and nanowires are viable options for scaling to 7 nm node and beyond. A general process flow for formation of a nanosheet stack involves removing sacrificial layers, which may be formed of Silicon Germanium (SiGe), between sheets of channel material, which may be formed of Silicon (Si).

### SUMMARY

Embodiments of the invention provide techniques for forming semiconductor structures with vertical silicon controlled rectifiers.

In one embodiment, a semiconductor structure includes a first set of one or more interconnects at a first side of the semiconductor structure, a second set of one or more interconnects at a second side of the semiconductor structure opposite the first side of the semiconductor structure, and a vertical silicon controlled rectifier having an anode junction, a cathode junction, a first gate junction and a second gate junction. The anode junction and the first gate junction of the vertical silicon controlled rectifier are wired to the first set of one or more interconnects at the first side of the semiconductor structure. The cathode junction of the vertical silicon controlled rectifier is wired to the second set of one or more interconnects at the second side of the semiconductor structure.

In another embodiment, a semiconductor structure includes back-end-of-line interconnects at a frontside of the semiconductor structure, a backside power delivery network at a backside of the semiconductor structure, and a vertical silicon controlled rectifier having (i) a first set of one or more junctions wired to the back-end-of-line interconnects at the frontside of the semiconductor structure and (ii) a second set of one or more junctions wired to the backside power delivery network at the backside of the semiconductor structure.

In another embodiment, an integrated circuit includes a semiconductor structure including a first set of one or more interconnects at a first side of the semiconductor structure, a second set of one or more interconnects at a second side of the semiconductor structure opposite the first side of the semiconductor structure, and a vertical silicon controlled rectifier having an anode junction, a cathode junction, a first gate junction and a second gate junction. The anode junction and the first gate junction of the vertical silicon controlled rectifier are wired to the first set of one or more interconnects at the first side of the semiconductor structure. The cathode junction of the vertical silicon controlled rectifier is wired to the second set of one or more interconnects at the second side of the semiconductor structure.

### BRIEF DESCRIPTION OF THE DRAWINGS

FIG. 1 shows a symbol, physical diagram and circuit for a silicon controlled rectifier, according to an embodiment of the invention.

FIG. 2 shows a cross-sectional view of a semiconductor structure including a vertical silicon controlled rectifier with anode, first gate and second gate junctions connected to frontside back-end-of-line interconnects and a cathode junction connected to backside interconnects, according to an embodiment of the invention.

FIG. 3 shows a cross-sectional view of a semiconductor structure including a vertical silicon controlled rectifier with anode and first gate junctions connected to frontside back-end-of-line interconnects, and cathode and second gate junctions connected to backside interconnects, according to an embodiment of the invention.

FIG. 4 shows a cross-sectional view of a semiconductor structure including a non-vertical silicon controlled rectifier with anode, cathode, first gate and second gate junctions connected to frontside back-end-of-line interconnects.

FIGS. 5A and 5B show cross-sectional views of a semiconductor structure following front-end-of-line processing, according to an embodiment of the invention.

FIGS. 6A and 6B show cross-sectional views of the structure of FIGS. 5A and 5B following formation of middle-of-line contacts and back-end-of-line interconnects, and following bonding to a carrier wafer, according to an embodiment of the invention.

FIGS. 7A and 7B show cross-sectional views of the structure of FIGS. 6A and 6B following a wafer flip and substrate removal, according to an embodiment of the invention.

FIGS. 8A and 8B show cross-sectional views of the structure of FIGS. 7A and 7B following removal of an etch stop layer, according to an embodiment of the invention.

FIGS. 9A and 9B show cross-sectional views of the structure of FIGS. 8A and 8B following formation of a backside interlayer dielectric layer, according to an embodiment of the invention.

FIGS. 10A and 10B show cross-sectional views of the structure of FIGS. 9A and 9B following patterning of the backside interlayer dielectric layer and a semiconductor layer, according to an embodiment of the invention.

FIGS. 11A and 11B show cross-sectional views of the structure of FIGS. 10A and 10B following growth of an epitaxial layer and backside contact metallization, according to an embodiment of the invention.

FIGS. 12A and 12B show cross-sectional views of the structure of FIGS. 11A and 11B following formation and patterning of additional backside interlayer dielectric material, according to an embodiment of the invention.

FIGS. 13A and 13B show cross-sectional views of the structure of FIGS. 12A and 12B following formation of spacers, backside metallization, and backside interconnects, according to an embodiment of the invention.

FIGS. 14A and 14B show cross-sectional views of another semiconductor structure following front-end-of-line processing, according to an embodiment of the invention.

FIGS. 15A and 15B show cross-sectional views of the structure of FIGS. 14A and 14B following formation of middle-of-line contacts and back-end-of-line interconnects, and following bonding to a carrier wafer, according to an embodiment of the invention.

FIGS. 16A and 16B show cross-sectional views of the structure of FIGS. 15A and 15B following a wafer flip and substrate removal, according to an embodiment of the invention.

FIGS. 17A and 17B show cross-sectional views of the structure of FIGS. 16A and 16B following removal of an etch stop layer, according to an embodiment of the invention.

FIGS. 18A and 18B show cross-sectional views of the structure of FIGS. 17A and 17B following formation of a backside interlayer dielectric layer, according to an embodiment of the invention.

FIGS. 19A and 19B show cross-sectional views of the structure of FIGS. 18A and 18B following patterning of the backside interlayer dielectric layer and a semiconductor layer, according to an embodiment of the invention.

FIGS. 20A and 20B show cross-sectional views of the structure of FIGS. 19A and 19B following growth of an epitaxial layer and backside contact metallization, according to an embodiment of the invention.

FIGS. 21A and 21B show cross-sectional views of the structure of FIGS. 20A and 20B following additional patterning of the backside interlayer dielectric layer and the semiconductor layer, according to an embodiment of the invention.

FIGS. 22A and 22B show cross-sectional views of the structure of FIGS. 21A and 21B following growth of an additional epitaxial layer and backside contact metallization, according to an embodiment of the invention.

FIGS. 23A and 23B show cross-sectional views of the structure of FIGS. 22A and 22B following formation and patterning of additional backside interlayer dielectric material, according to an embodiment of the invention.

FIGS. 24A and 24B show cross-sectional views of the structure of FIGS. 23A and 23B following formation of spacers, backside metallization, and backside interconnects, according to an embodiment of the invention.

FIG. 25 shows an integrated circuit comprising one or more semiconductor structures with vertical silicon controlled rectifiers, according to an embodiment of the invention.

### DETAILED DESCRIPTION

Illustrative embodiments of the invention may be described herein in the context of illustrative methods for forming semiconductor structures with vertical silicon controlled rectifiers, along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

As described above, the use of stacked nanosheet channels provide techniques useful for reducing the size of field-effect transistors (FETs). A FET is a transistor having a source, a gate, and a drain, and having action that depends on the flow of majority carriers along a channel that runs past the gate between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Semiconductor devices, including integrated circuits, are sensitive to electrostatic discharge (ESD) events. An ESD event, for example, may result in one or more pulses of a short duration with high current that can lead to failure of a device. Thus, semiconductor devices may integrate ESD protection circuitry. A silicon controlled rectifier (SCR) is a type of ESD protection circuitry which may be integrated with semiconductor devices to provide a discharge path during ESD events (e.g., where an SCR changes to a conductive state when an ESD event is detected to shunt current to ground, with the SCR maintaining the conductive state until voltage is discharged to a safe level).

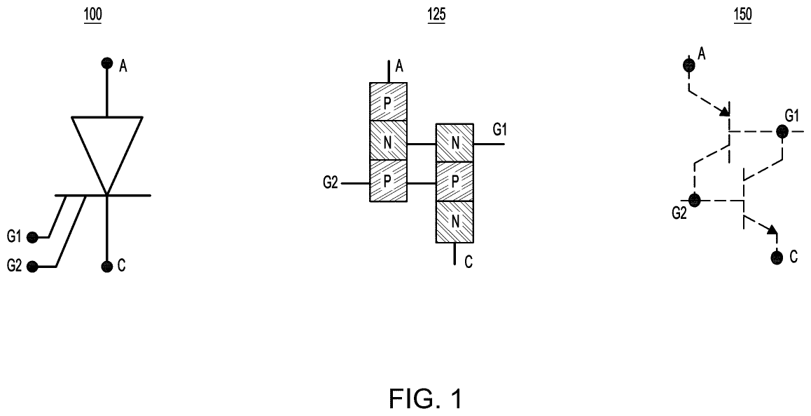

SCRs have a wide range of applications for handling high currents and voltages, and thus serve as an effective switch in various electronic systems. For example, SCRs may be used for radiofrequency (RF) ESD protection. FIG. 1 shows a symbolic representation 100 of an SCR, including terminals A (anode), C (cathode), G1 (first gate) and G2 (second gate). FIG. 1 also shows a physical diagram 125 of an SCR, showing the A, C, G1 and G2 junctions (also referred to as terminals or connections) connected to different doped semiconductor layers (where N denotes an n-type semiconductor and P denotes a p-type semiconductor). FIG. 1 further shows an equivalent circuit diagram 150 for the SCR. Key metrics for ESD SCRs include the failure current, I_{fail} [milliamperes per micrometer squared (mA/μm²)] and the ratio of the failure current to the capacitive load, denoted I_{fail}/C_{load} [milliamperes per femtofarad (mA/fF)].

A general process flow for forming a vertical SCR structure may include formation of one or more active devices in front-end-of-line (FEOL) processing, followed by middle-of-line (MOL) contact and back-end-of-line (BEOL) interconnect formation (e.g., for connections including the anode (A) junction, the first gate (G1) junction and the second gate (G2) junction of the vertical SCR). The structure is then bonded to a carrier wafer, followed by a wafer flip and substrate removal which stops on an etch stop layer. The etch stop layer is then removed, followed by backside interlayer dielectric (ILD) deposition, backside well patterning, and low temperature trench epitaxial growth and contact metallization (e.g., for a cathode (C) junction of the vertical SCR). Next, additional backside ILD deposition and backside metallization layer (e.g., M1) patterning is performed. Spacers are then formed, followed by backside metallization layer formation and additional backside interconnect formation.

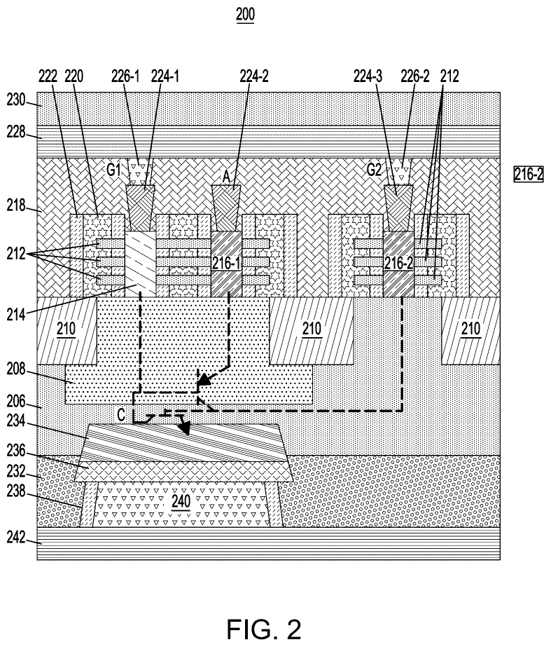

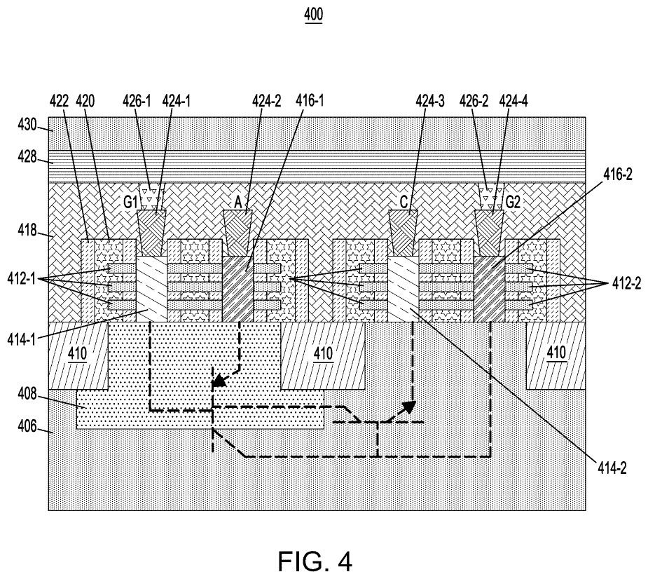

FIG. 2 shows a cross-sectional view 200 of a semiconductor structure including a first well region 206, a second well region 208, shallow trench isolation (STI) regions 210, nanosheet channel layers 212, source/drain region 214, source/drain regions 216-1 and 216-2, ILD layer 218, gates 220, spacers 222, MOL contacts 224-1, 224-2 and 224-3 (collectively, MOL contacts 224), metallization layers 226-1 and 226-2 (collectively, metallization layers 226), BEOL interconnects 228, a carrier wafer 230, a backside ILD layer 232, a backside epitaxial layer 234, a backside contact 236, spacer 238, metallization layer 240, and backside interconnects 242. The first well region 206 may be a p-well region, and the second well region 208 may be an n-well region. The source/drain region 214 and the epitaxial layer 234 may be N+ doped, while the source/drain regions 216-1 and 216-2 may be P+ doped. The structure shown in FIG. 2 also labels junctions of the vertical SCR, and overlays the equivalent SCR circuit in dashed outline. The vertical SCR in FIG. 2 has the anode (A) junction being provided by the MOL contact 224-2 connected to the source/drain region 216-1, the first gate (G1) junction being provided by the MOL contact 224-1 connected to the source/drain region 214, the second gate (G2) junction being provided by the MOL contact 224-2 connected to the source/drain region 216-2, and the cathode (C) junction being provided by the backside contact 236 connected to the backside epitaxial layer 234. Here, the vertical SCR has the anode (A) junction, the first gate (G1) junction and the second gate (G2) junction wired to the frontside via the BEOL interconnects 228, and has the cathode (C) junction wired to the backside interconnects 242. The cathode (C) junction and its contact (backside contact 236) along with its metal wiring (metallization layer 240) are advantageously formed on the backside under the three other junctions for the anode (A), the first gate (G1) and the second gate (G2). Thus, the vertical SCR shown in FIG. 2 reduces the total SCR device area by approximately 25% (e.g., as compared to the non-vertical SCR device shown in the cross-sectional view 400 of FIG. 4).

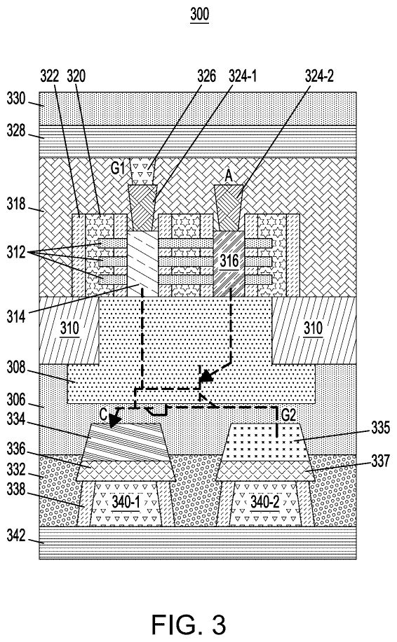

FIG. 3 shows a cross-sectional view 300 of a semiconductor structure including a first well region 306, a second well region 308, STI regions 310, nanosheet channel layers 312, source/drain region 314, source/drain region 316, ILD layer 318, gates 320, spacers 322, MOL contacts 324-1 and 324-2 (collectively, MOL contacts 324), metallization layer 326, BEOL interconnects 328, a carrier wafer 330, a backside ILD layer 332, a first backside epitaxial layer 334, a first backside contact 336, a second backside epitaxial layer 335, a second backside contact 337, spacers 338, backside metallization layers 340-1 and 340-2 (collectively, backside metallization layers 340), and backside interconnects 342. The first well region 306 may be a p-well region, and the second well region 308 may be an n-well region. The source/drain region 314 and the first backside epitaxial layer 334 may be N+ doped, while the source/drain region 316 and the second backside epitaxial layer 335 may be P+ doped. The structure shown in FIG. 3 also labels junctions of the vertical SCR, and overlays the equivalent SCR circuit in dashed outline. The vertical SCR in FIG. 3 has the anode (A) junction being provided by the MOL contact 324-2 connected to the source/drain region 316, the first gate (G1) junction being provided by the MOL contact 324-1 connected to the source/drain region 314, the second gate (G2) junction being provided by the second backside contact 337 to the second backside epitaxial layer 335, and the cathode (C) junction being provided by the first backside contact 336 connected to the first backside epitaxial layer 334. Here, the vertical SCR has the anode (A) junction and the first gate (G1) junction wired to the frontside via the BEOL interconnects 328, and has the cathode (C) junction and the second gate (G2) junction wired to the backside interconnects 342. The cathode (C) junction and its contact (the first backside contact 336) along with its metal wiring (metallization layer 340-1), as well as the second gate (G2) junction and its contact (the second backside contact 337) along with its metal wiring (metallization layer 340-2) are advantageously formed on the backside under the two other junctions for the anode (A) and the first gate (G1). Thus, the vertical SCR shown in FIG. 3 reduces the total SCR device area by approximately 50% (e.g., as compared to the non-vertical SCR device shown in the cross-sectional view 400 of FIG. 4).

FIG. 4 shows a cross-sectional view 400 of a semiconductor structure including a first well region 406, a second well region 408, STI regions 410, nanosheet channel layers 412-1 and 412-2 (collectively, nanosheet channel layers 412), source/drain regions 414-1 and 414-2 (collectively, source/drain regions 414), source/drain regions 416-1 and 416-2 (collectively, source/drain regions 416), ILD layer 418, gates 420, spacers 422, MOL contacts 424-1 through 424-4 (collectively, MOL contacts 424), metallization layers 426-1 and 426-2 (collectively, metallization layers 426), BEOL interconnects 428, and a carrier wafer 430. The first well region 406 may be a p-well region, and the second well region 408 may be an n-well region. The source/drain regions 414 may be N+ doped, while the source/drain regions 416 may be P+ doped. The structure shown in FIG. 4 also labels junctions of a non-vertical SCR, and overlays the equivalent SCR circuit in dashed outline. The non-vertical SCR in FIG. 4 has the anode (A) junction being provided by the MOL contact 424-2 connected to the source/drain region 416-1, the first gate (G1) junction being provided by the MOL contact 424-1 connected to the source/drain region 414-1, the second gate (G2) junction being provided by the MOL contact 424-4 connected to the source/drain region 416-2, and the cathode (C) junction being provided by the MOL contact 424-3 connected to the source/drain region 414-2. Here, the non-vertical SCR has the anode (A) junction, the cathode (C) junction, the first gate (G1) junction and the second gate (G2) junction wired to the frontside via the BEOL interconnects 428. Thus, the non-vertical SCR shown in FIG. 4 has an increased total SCR device area relative to the vertical SCR devices shown in FIGS. 2 and 3.

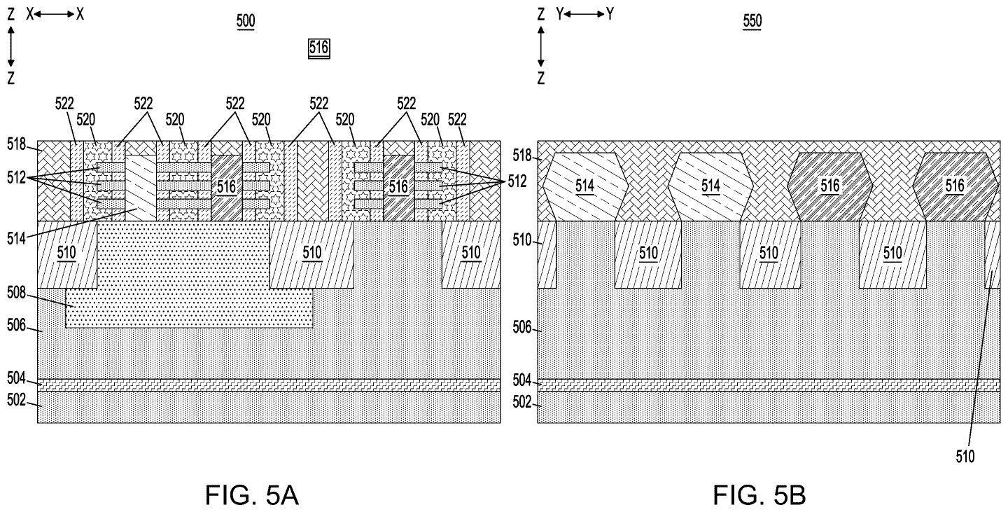

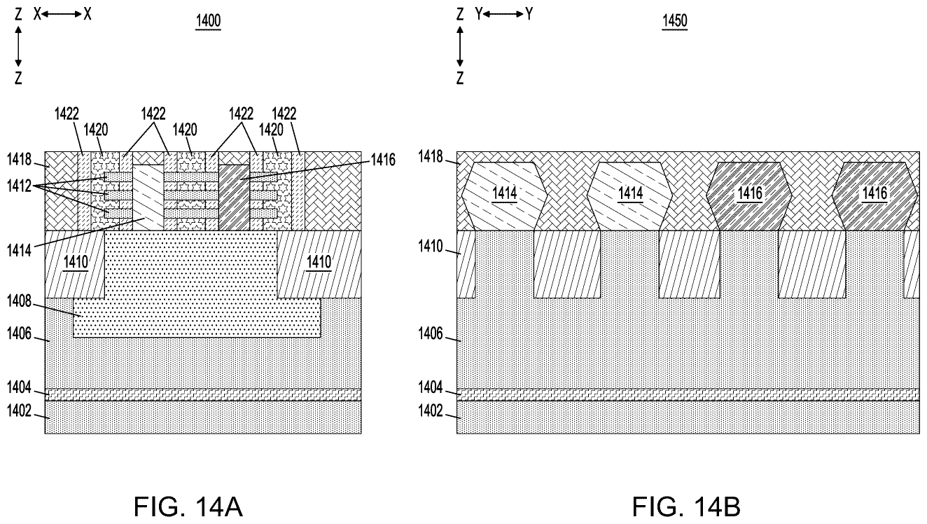

FIGS. 5A-24B show process flows for forming vertical SCRs in semiconductor structures. More particularly, FIGS. 5A-13B show a process flow for forming the structure shown in the cross-sectional view 200 of FIG. 2, while FIGS. 14A-24B show a process flow for forming the structure shown in the cross-sectional view 300 of FIG. 3.

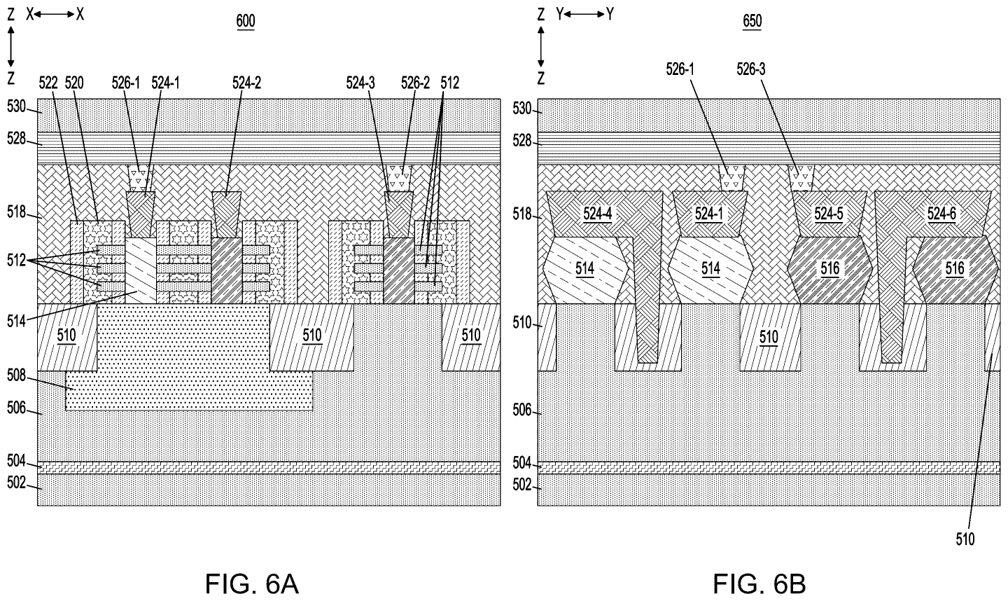

FIGS. 5A and 5B show different views of a semiconductor structure. FIG. 5A shows a first cross-sectional view 500 of the semiconductor structure, and FIG. 5B shows a second cross-sectional view 550 of the semiconductor structure. The cross-sectional view 500 of FIG. 5A, and subsequent cross-sectional views 600, 700, 800, 900, 1000, 1100, 1200 and 1300 of FIGS. 6A, 7A, 8A, 9A, 10A, 11A, 12A and 13A, respectively, are taken across source/drain regions in an SCR-dense region. The cross-sectional view 550 of FIG. 5B, and subsequent cross-sectional views 650, 750, 850, 950, 1050, 1150, 1250 and 1350 of FIGS. 6B, 7B, 8B, 9B, 10B, 11B, 12B and 13B, respectively, are taken along source/drain regions in a transistor region. The semiconductor structure of FIGS. 5A and 5B is shown after FEOL processing, including a substrate 502, an etch stop layer 504, a first well region 506, a second well region 508, STI regions 510, nanosheet channel layers 512, source/drain regions 514 and 516, ILD layer 518, gates 520, and spacers 522.

The substrate 502 may be formed of any suitable semiconductor structure, including various silicon-containing materials including but not limited to silicon (Si), silicon germanium (SiGe), silicon germanium carbide (SiGeC), silicon carbide (SIC) and multi-layers thereof. Although silicon is the predominantly used semiconductor material in wafer fabrication, alternative semiconductor materials can be employed as additional layers, such as, but not limited to, germanium (Ge), gallium arsenide (GaAs), gallium nitride (GaN), SiGe, cadmium telluride (CdTe), zinc selenide (ZnSe), etc. The substrate 502 may have a height (in direction Z) and widths (in directions X/Y) which vary as needed based on the type of structures to be formed.

The etch stop layer 504 may be formed of SiGe or another material which may be etched selective to the material used for the substrate 502. The etch stop layer 504 may have a thickness (in direction Z) in the range of 10 to 40 nm.

The first well region 506 and the second well region 508 may have opposite polarity. For example, the first well region 506 may be a p-well while the second well region 508 is an n-well.

The STI regions 510 may be formed of a dielectric material such as silicon dioxide (SiO₂), silicon oxycarbide (SiOC), silicon oxynitride (SiON), etc. The STI regions 510 may have a height (in direction Z) in the range of 10 to 200 nm, and widths (in directions X/Y) that are defined by a spacing between patterned nanosheet stacks formed over the substrate 502.

The nanosheet channel layers 512 will provide channels for transistors in a transistor structure. The nanosheet channel layers 512 may be formed of Si or another suitable material (e.g., a material similar to that used for the substrate 102). Each of the nanosheet channel layers 512 may have a thickness (in direction Z) in the range of 5-15 nm.

The source/drain regions 514 and 516 may be formed using epitaxial growth processes. The source/drain regions 514 and 516 may have different doping. For example, the source/drain regions 514 may be n-type while the source/drain regions 516 are p-type. The source/drain regions 514 and 516 may be suitably doped using ion implantation, gas phase doping, plasma doping, plasma immersion ion implantation, cluster doping, infusion doping, liquid phase doping, solid phase doping, etc. N-type dopants may be selected from a group of phosphorus (P), arsenic (As) and antimony (Sb). P-type dopants may be selected from a group of boron (B), boron fluoride (BF₂), gallium (Ga), indium (In), and thallium (TI). In some embodiments, the epitaxy processes used to form the source/drain regions 514 and 516 utilize in-situ doping (dopants are incorporated in epitaxy material during epitaxy). Epitaxial materials may be grown from gaseous or liquid precursors. Epitaxial materials may be grown using vapor-phase epitaxy (VPE), molecular-beam epitaxy (MBE), liquid-phase epitaxy (LPE), rapid thermal chemical vapor deposition (RTCVD), metal organic chemical vapor deposition (MOCVD), ultra-high vacuum chemical vapor deposition (UHVCVD), low-pressure chemical vapor deposition (LPCVD), limited reaction processing CVD (LRPCVD), or other suitable processes. Epitaxial Si, SiGe, Ge, and/or carbon doped silicon (Si:C) can be doped during deposition (in-situ doped) by adding dopants, such as n-type or p-type dopants. The dopant concentration in the source/drain can range from 1×10¹⁹ cm⁻³ to 3×10²¹ cm⁻³, or preferably between 2×10²⁰ cm⁻³ to 3×10²¹ cm⁻³.

The ILD layer 518 may be formed by filling the structure with an ILD material, followed by planarization (e.g., using chemical mechanical planarization (CMP)). The ILD layer 518 may be formed of any suitable isolating material, such as SiO₂, SiOC, SiON, etc.

The gates 520 may comprise gate stacks formed using replacement metal gate (RMG) processing. The gate stacks may include a gate dielectric and a gate conductor. The gate dielectric may be conformally deposited in the structure, and may be formed of a high-k material. Examples of high-k materials include but are not limited to metal oxides such as HfO₂, hafnium silicon oxide (Hf—Si—O), hafnium silicon oxynitride (HfSiON), lanthanum oxide (La₂O₃), lanthanum aluminum oxide (LaAlO₃), zirconium oxide (ZrO₂), zirconium silicon oxide, zirconium silicon oxynitride, tantalum oxide (Ta₂O₅), titanium oxide (TiO₂), barium strontium titanium oxide, barium titanium oxide, strontium titanium oxide, yttrium oxide (Y₂O₃), aluminum oxide (Al₂O₃), lead scandium tantalum oxide, and lead zinc niobate. The high-k material may further include dopants such as lanthanum (La), aluminum (Al), and magnesium (Mg). The gate dielectric may have a uniform thickness in the range of Inm to 3 nm. The gate conductor may include a gate work function metal (WFM) layer and a gate metal layer. The gate WFM layer may be formed of a WFM such as titanium (Ti), titanium nitride (TiN), tantalum (Ta), tantalum nitride (TaN), aluminum (Al), titanium aluminum (TiAl), titanium aluminum carbon (TiAlC), a combination of Ti and Al alloys, a stack which includes a barrier layer (e.g., of TiN, TaN, etc.) followed by one or more of the aforementioned WFM materials, etc. The gate WFM layer may have a uniform thickness in the range of 1 to 10 nm. The gate metal layer may comprise a conductive metal (e.g., tungsten (W)).

The spacers 522 include gate spacers surrounding the gates 520, as well as inner spacers formed between the nanosheet channel layers 512 adjacent the source/drain regions 514 and 516 as illustrated. The spacers 522 may be formed of silicon boron carbide nitride (SiBCN) or another suitable material such as SiN, SiOC, silicon oxycarbonitride (SiOCN), etc. The spacers 522 may have a thickness (in direction X) in the range of 4 to 10 nm.

FIGS. 6A and 6B show first and second cross-sectional views 600 and 650, respectively, of the structure of FIGS. 5A and 5B following formation of middle-of-line (MOL) contacts 524-1 through 524-6 (collectively, MOL contacts 524) and metallization layers 526-1 through 526-3 (collectively, metallization layers 526) and BEOL interconnects 528, and following bonding to a carrier wafer 530. The MOL contacts 524 may be formed of a silicide layer such as nickel silicide (NiSi), titanium silicide (TiSi), nickel platinum silicide (NiPtSi), a metal adhesion layer such as titanium nitride (TiN) and one or more low resistance metal fill materials such as tungsten (W), ruthenium (Ru), cobalt (Co), etc., and the metallization layers 526 may be formed of a metal adhesion layer such as TiN and one or more low resistance metal fill materials such as Cu, W, Ru, Co, etc. The MOL contacts 524-1 and 524-4 are formed to different ones of the source/drain regions 514, and the MOL contacts 524-2, 524-3, 524-5 and 524-6 are formed to different ones of the source/drain regions 516. The metallization layers 526-1, 526-2 and 526-3 are formed to the MOL contacts 524-1, 524-3 and 524-5, respectively. The MOL contact 524-2 provides the anode (A) junction of a vertical SCR, while the MOL contact 524-1 provides the first gate (G1) junction of the vertical SCR and the MOL contact 524-3 provides the second gate (G2) junction of the vertical SCR. The carrier wafer 530 may be formed of Si or another material similar to that used for the substate 502.

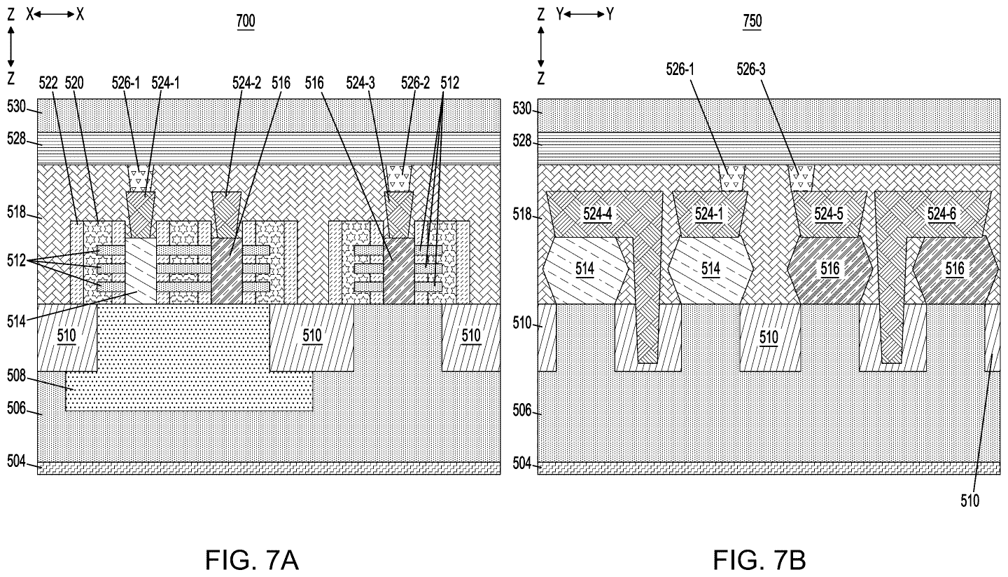

FIGS. 7A and 7B show first and second cross-sectional views 700 and 750, respectively, of the structure of FIGS. 6A and 6B following a wafer flip and removal of the substrate 502. The wafer is flipped utilizing the carrier wafer 530, and the substrate 502 is then removed from the backside utilizing a suitable etch process (e.g., reactive-ion etching (RIE)). The etch process stops on the etch stop layer 504.

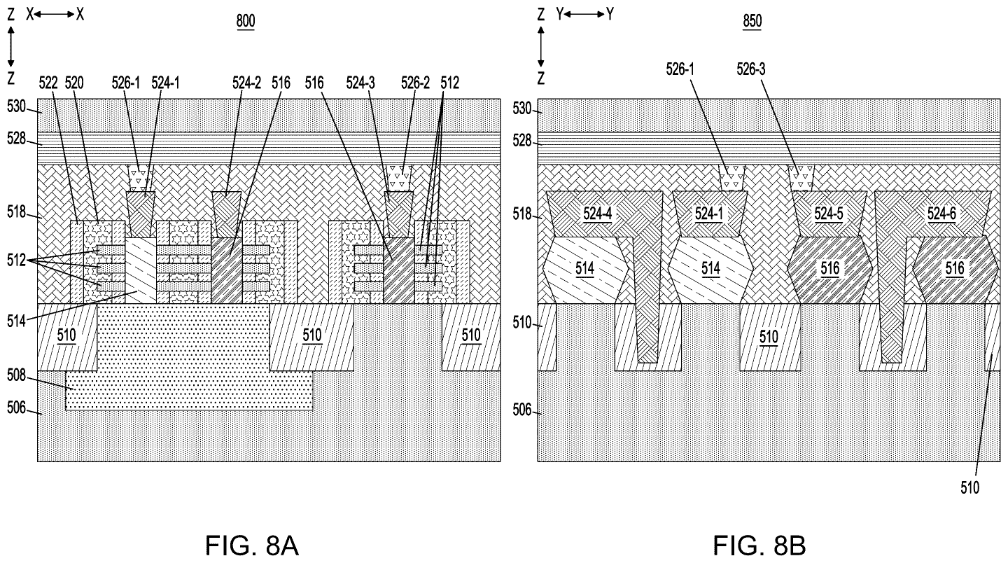

FIGS. 8A and 8B show first and second cross-sectional views 800 and 850, respectively, of the structure of FIGS. 7A and 7B following removal of the etch stop layer 504. The etch stop layer 504 may be removed utilizing a suitable etch process (e.g., RIE).

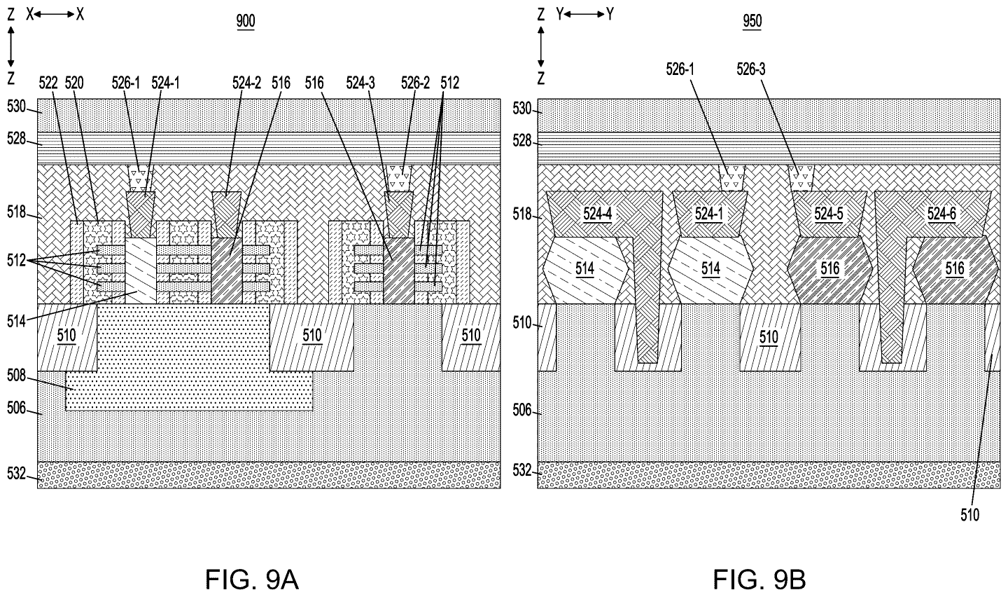

FIGS. 9A and 9B show first and second cross-sectional views 900 and 950, respectively, of the structure of FIGS. 8A and 8B following formation of a backside ILD layer 532. Material for the backside ILD layer 532 may be filled and then planarized (e.g., using chemical mechanical planarization (CMP)). The backside ILD layer 532 may be formed of similar materials as the ILD layer 518.

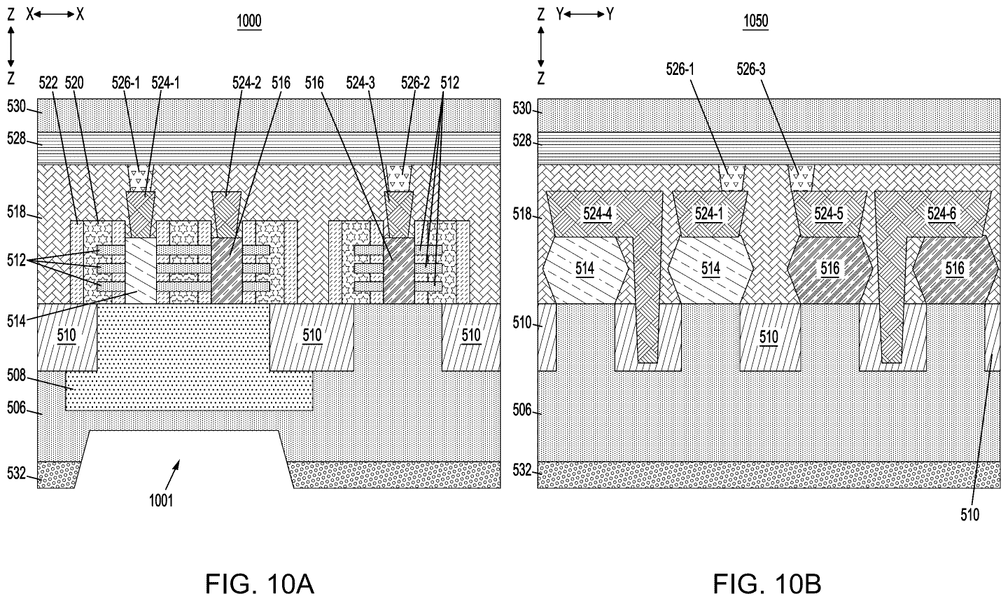

FIGS. 10A and 10B show first and second cross-sectional views 1000 and 1050, respectively, of the structure of FIGS. 9A and 9B following patterning for a backside epitaxial layer. The patterning may utilize lithography, where a mask layer is formed over the backside ILD layer 532 to expose the area (e.g., opening 1001) where the backside epitaxial layer will be formed. The backside ILD layer 532 and a portion of the well region 508 exposed by the masking layer is then etched utilizing one or more suitable etch processes.

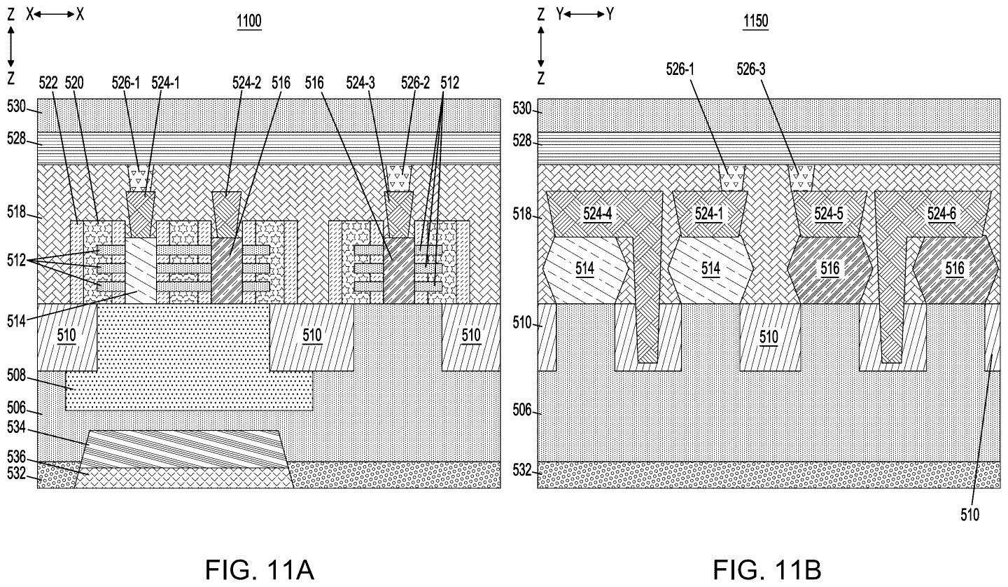

FIGS. 11A and 11B show first and second cross-sectional views 1100 and 1150, respectively, of the structure of FIGS. 10A and 10B following growth of a backside epitaxial layer 534 and backside contact 536. The backside epitaxial layer 534 may be formed utilizing a low temperature epitaxial growth process. The backside epitaxial layer 534 may utilize a same doping as the source/drain regions 514 (e.g., N+). The backside contact 536 may be formed of similar materials as the MOL contacts 524. The backside contact 536 provides the cathode (C) junction of the vertical SCR.

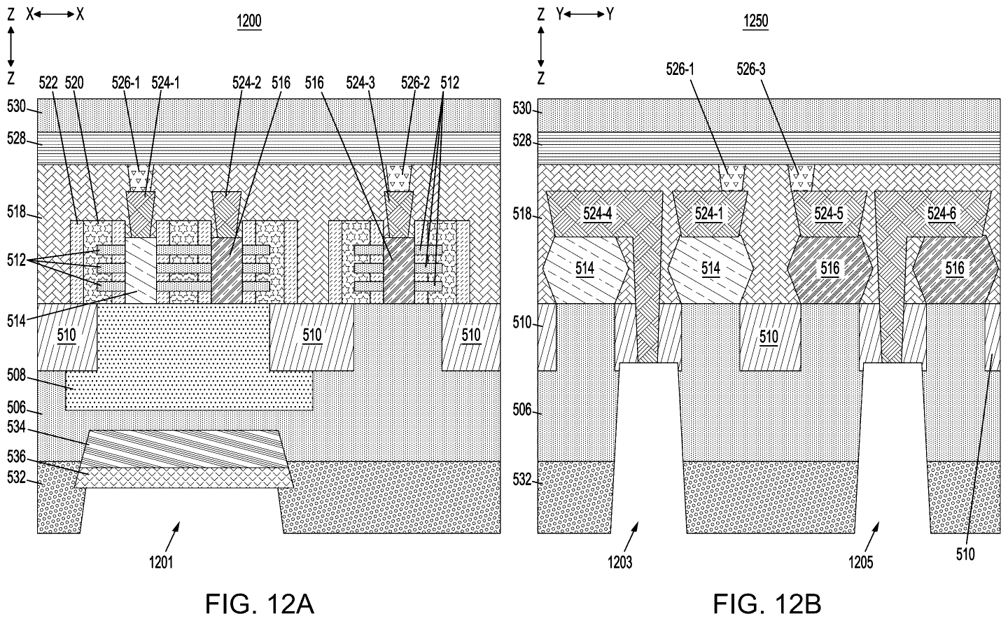

FIGS. 12A and 12B show first and second cross-sectional views 1200 and 1250, respectively, of the structure of FIGS. 11A and 11B following deposition of additional material for the backside ILD layer 532, and following patterning of openings 1201, 1203 and 1205 in the backside ILD layer 532 and the well region 506 for a backside metal level (M1). The opening 1201 exposes the backside contact 536, while the opening 1203 exposes the MOL contact 524-4 and the opening 1205 exposes the MOL contact 524-6.

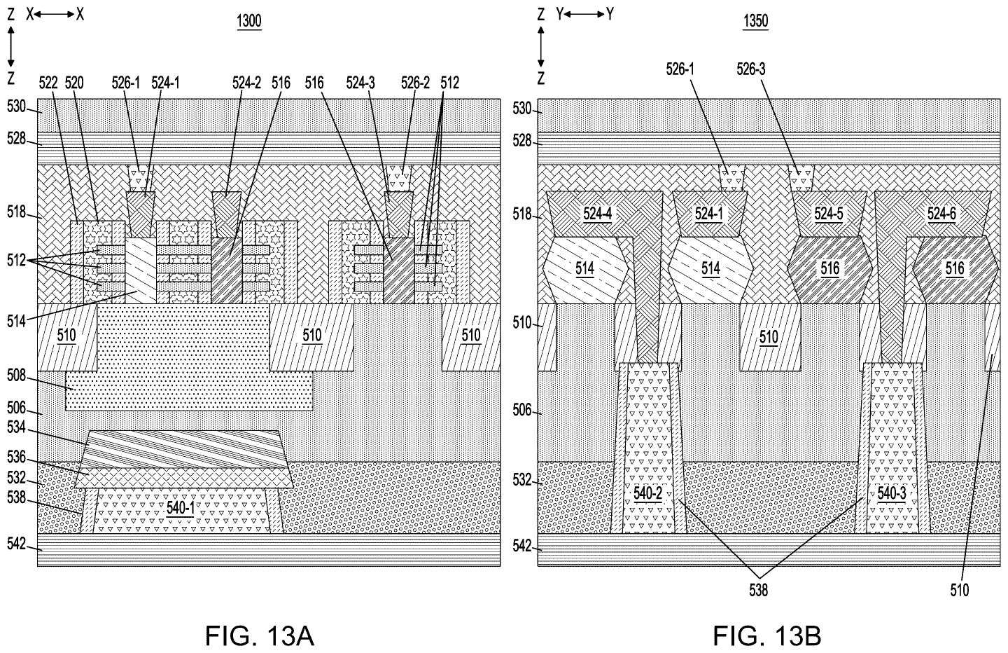

FIGS. 13A and 13B show first and second cross-sectional views 1300 and 1350, respectively, of the structure of FIGS. 12A and 12B following formation of spacers 538, backside metallization layers 540-1, 540-2 and 540-3 (collectively, backside metallization layers 540), and backside interconnects 542. The spacers 538 may be formed of any suitable dielectric material, such as SiO2, SIN, SIOCN, SiC, SiCO, etc., and may have a thickness in the range of 6 to 15 nm. The backside metallization layers 540 are then filled and planarized, followed by formation of the backside interconnects 542.

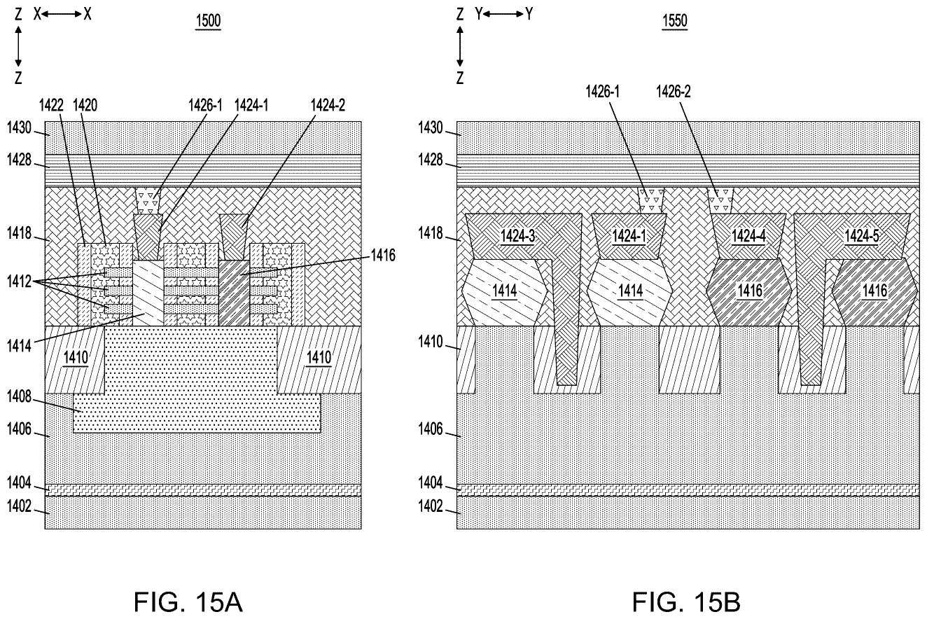

FIGS. 14A and 14B show different views of a semiconductor structure. FIG. 14A shows a first cross-sectional view 1400 of the semiconductor structure, and FIG. 14B shows a second cross-sectional view 1450 of the semiconductor structure. The cross-sectional view 1400 of FIG. 14A, and subsequent cross-sectional views 1500, 1600, 1700, 1800, 1900, 2000, 2100, 2200, 2300 and 2400 of FIGS. 15A, 16A, 17A, 18A, 19A, 20A, 21A, 22A, 23A and 24A, respectively, are taken across source/drain regions in an SCR-dense region. The cross-sectional view 1450 of FIG. 14B, and subsequent cross-sectional views 1550, 1650, 1750, 1850, 1950, 2050, 2150, 2250, 2350 and 2450 of FIGS. 15B, 16B, 17B, 18B, 19B, 20B, 21B, 22B, 23B and 24B, respectively, are taken along source/drain regions in a transistor region. The semiconductor structure of FIGS. 14A and 14B is shown after FEOL processing, including a substrate 1402, an etch stop layer 1404, a first well region 1406, a second well region 1408, STI regions 1410, nanosheet channel layers 1412, source/drain regions 1414 and 1416, ILD layer 1418, gates 1420 and spacers 1422, which are formed of similar materials and with similar sizing and processing as that described above with respect to the substrate 502, the etch stop layer 504, the first well region 506, the second well region 508, the STI regions 510, the nanosheet channel layers 512, the source/drain regions 514 and 516, the ILD layer 518, the gates 520 and the spacers 522, respectively.

FIGS. 15A and 15B show first and second cross-sectional views 1500 and 1550, respectively, of the structure of FIGS. 14A and 14B following formation of MOL contacts 1424-1 through 1424-5 (collectively, MOL contacts 1424) and metallization layers 1426-1 and 1426-2 (collectively, metallization layers 1426) and BEOL interconnects 1428, and following bonding to a carrier wafer 1430. The MOL contacts 1424, the metallization layers 1426 and the carrier wafer 1430 may be formed of similar materials, and with similar sizing and processing as that described above with respect to the MOL contacts 524, the metallization layers 526 and the carrier wafer 530, respectively. The MOL contacts 1424-1 and 1424-3 are formed to different ones of the source/drain regions 1414, and the MOL contacts 1424-2, 1424-4 and 1424-5 are formed to different ones of the source/drain regions 1416. The metallization layer 1426-1 is formed to the MOL contact 1424-1 and the metallization layer 1426-2 is formed to the MOL contact 1424-4.

The MOL contact 1424-2 provides the anode (A) junction of a vertical SCR, while the MOL contact 1424-1 provides the first gate (G1) junction of the vertical SCR. It should be noted that, whereas the process flow described above with respect to FIGS. 5A-13B illustrates formation of a structure where the second gate (G2) junction of a vertical SCR is also at the frontside of the structure, in the process flow of FIGS. 14A-24B the second gate (G2) junction of the vertical SCR will be formed at the backside of the structure.

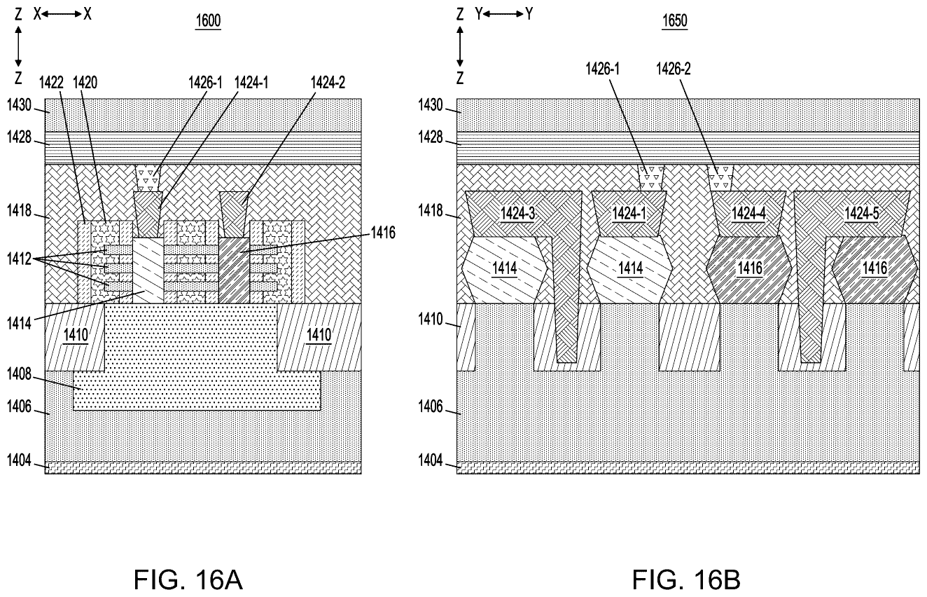

FIGS. 16A and 16B show first and second cross-sectional views 1600 and 1650, respectively, of the structure of FIGS. 15A and 15B following a wafer flip and removal of the substrate 1402. The wafer is flipped utilizing the carrier wafer 1530, and the substrate 1502 is then removed from the backside utilizing a suitable etch process (e.g., RIE). The etch process stops on the etch stop layer 1404.

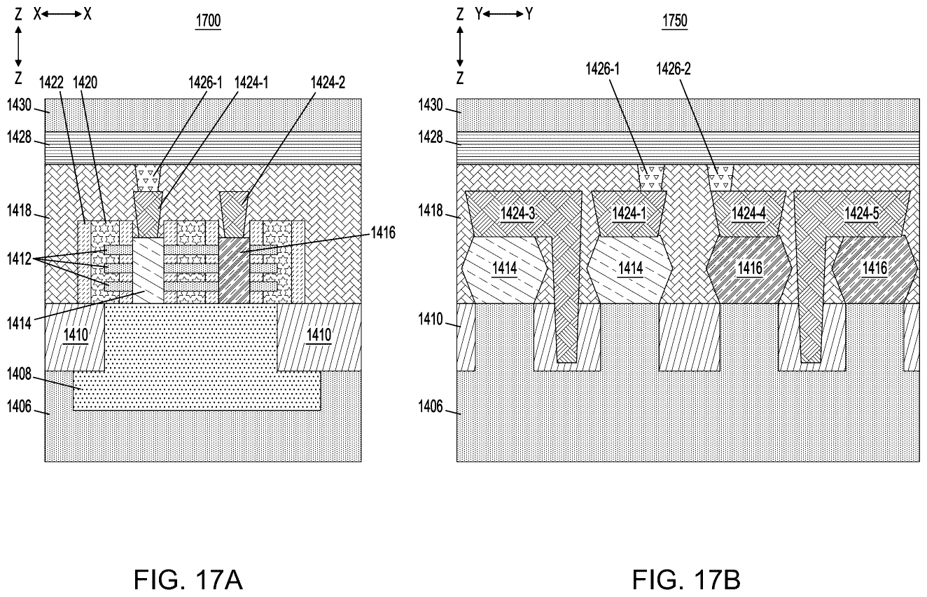

FIGS. 17A and 17B show first and second cross-sectional views 1700 and 1750, respectively, of the structure of FIGS. 16A and 16B following removal of the etch stop layer 1404. The etch stop layer 1404 may be removed utilizing a suitable etch process (e.g., RIE).

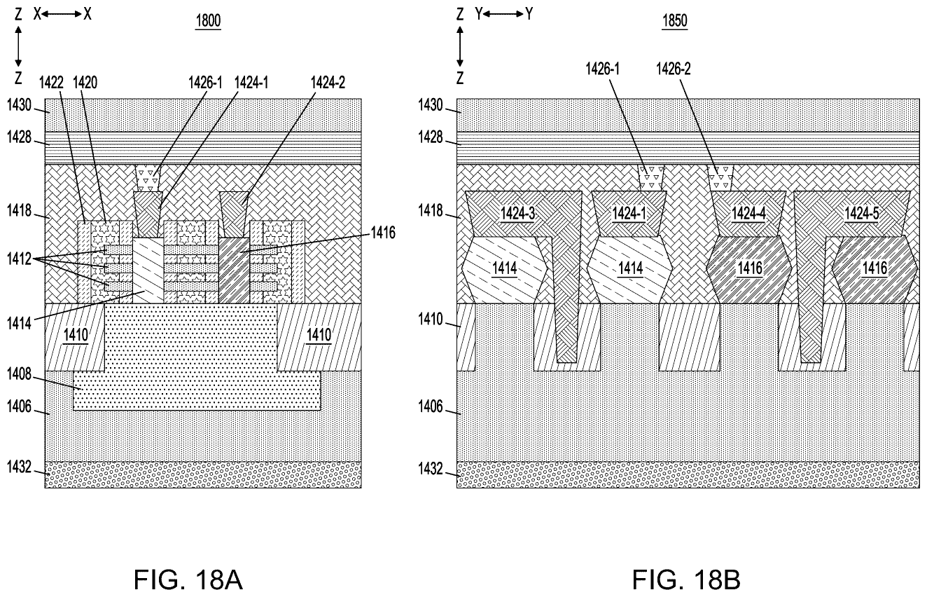

FIGS. 18A and 18B show first and second cross-sectional views 1800 and 1850, respectively, of the structure of FIGS. 17A and 17B following formation of a backside ILD layer 1432. The backside ILD layer 1432 may be formed of similar materials, and with similar sizing and processing as that described above with respect to the backside ILD layer 532.

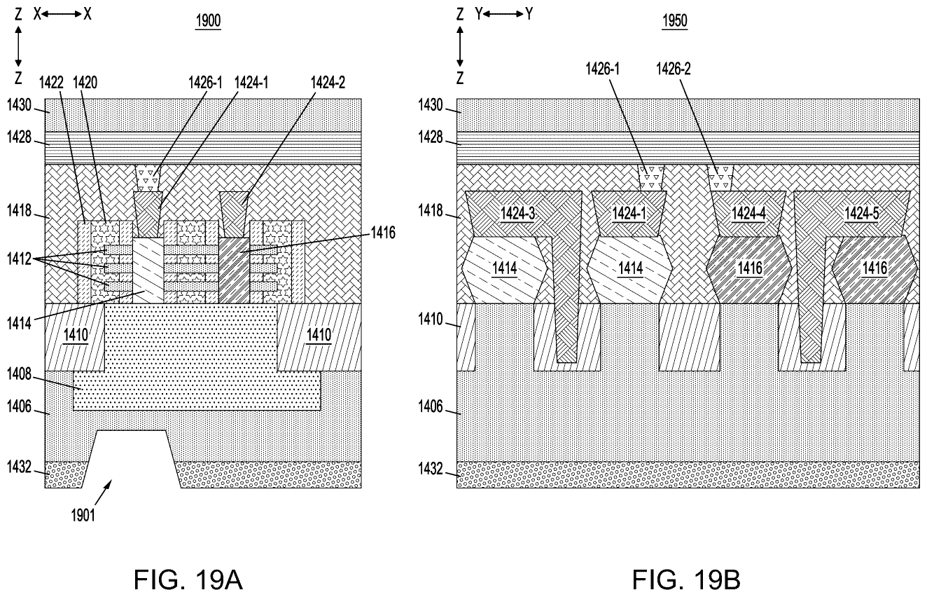

FIGS. 19A and 19B show first and second cross-sectional views 1900 and 1950, respectively, of the structure of FIGS. 18A and 18B following patterning for a first backside epitaxial layer. The patterning may utilize lithography, where a mask layer is formed over the backside ILD layer 1432 to expose the area (e.g., opening 1901) where the first backside epitaxial layer will be formed. The backside ILD layer 1432 and a portion of the well region 1408 exposed by the masking layer is then etched utilizing one or more suitable etch processes.

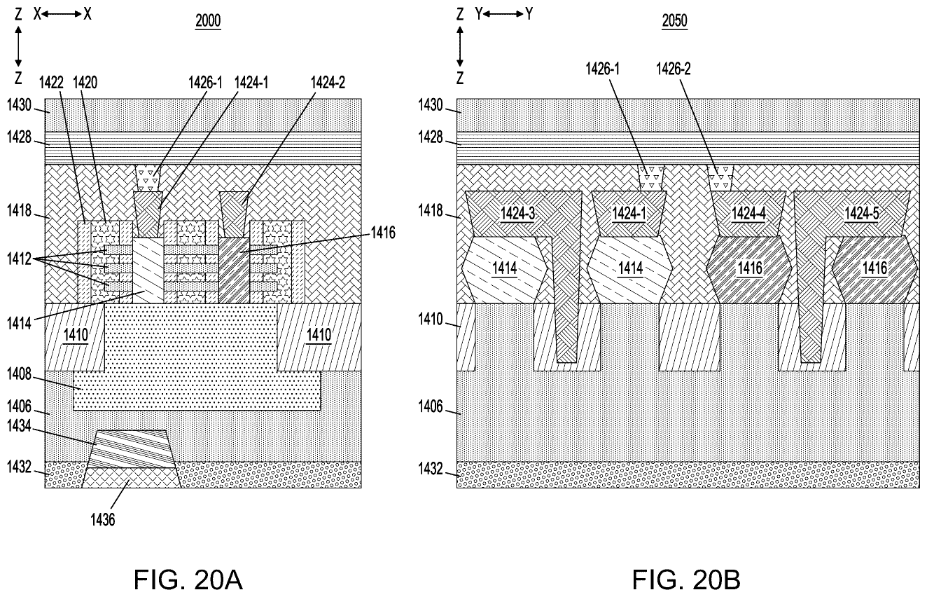

FIGS. 20A and 20B show first and second cross-sectional views 2000 and 2050, respectively, of the structure of FIGS. 19A and 19B following growth of a first backside epitaxial layer 1434 and a first backside contact 1436. The first backside epitaxial layer 1434 may be formed utilizing a low temperature epitaxial growth process. The first backside epitaxial layer 1434 may utilize a same doping as the source/drain regions 1414 (e.g., N+). The backside contact 1436 may be formed of similar materials as the backside contact 536. The backside contact 536 provides the cathode (C) connection of the vertical SCR.

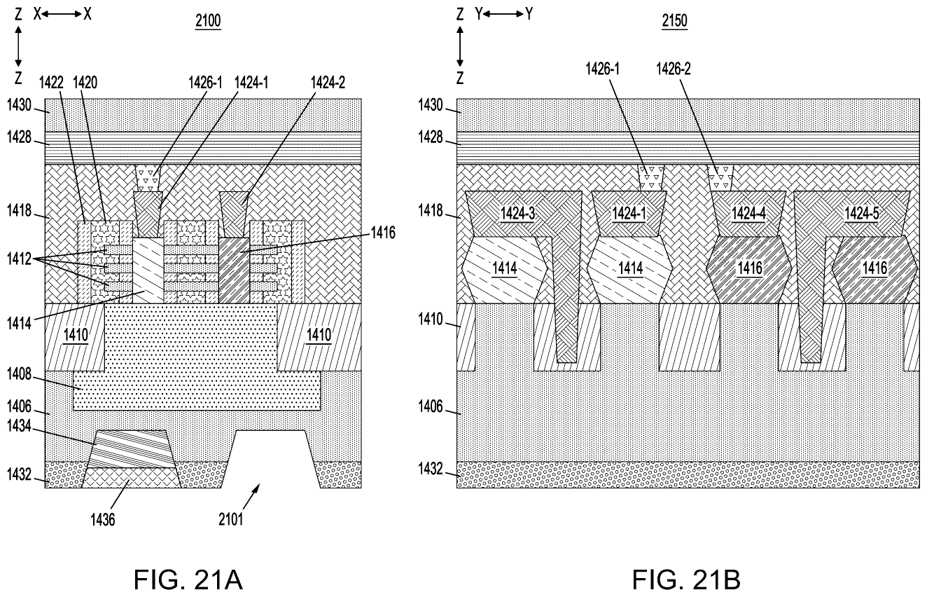

FIGS. 21A and 21B show first and second cross-sectional views 2100 and 2150, respectively, of the structure of FIGS. 20A and 20B following patterning for a second backside epitaxial layer. The patterning may utilize lithography, where a mask layer is formed over the backside ILD layer 1432 to expose the area (e.g., opening 2101) where the second backside epitaxial layer will be formed. The backside ILD layer 1432 and a portion of the well region 1408 exposed by the masking layer is then etched utilizing one or more suitable etch processes.

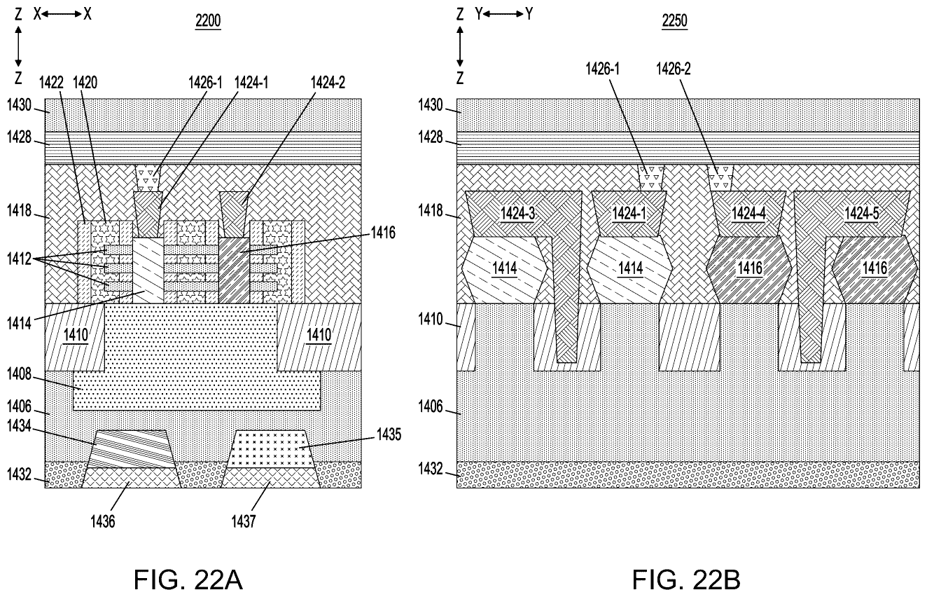

FIGS. 22A and 22B show first and second cross-sectional views 2200 and 2250, respectively, of the structure of FIGS. 21A and 21B following growth of a second backside epitaxial layer 1435 and a second backside contact 1437. The second backside epitaxial layer 1434 may be formed utilizing a low temperature epitaxial growth process. The second backside epitaxial layer 1435 may utilize a same doping as the source/drain regions 1416 (e.g., P+). The backside contact 1437 may be formed of similar materials as the backside contact 536. The backside contact 1437 provides the second gate (G2) junction of the vertical SCR.

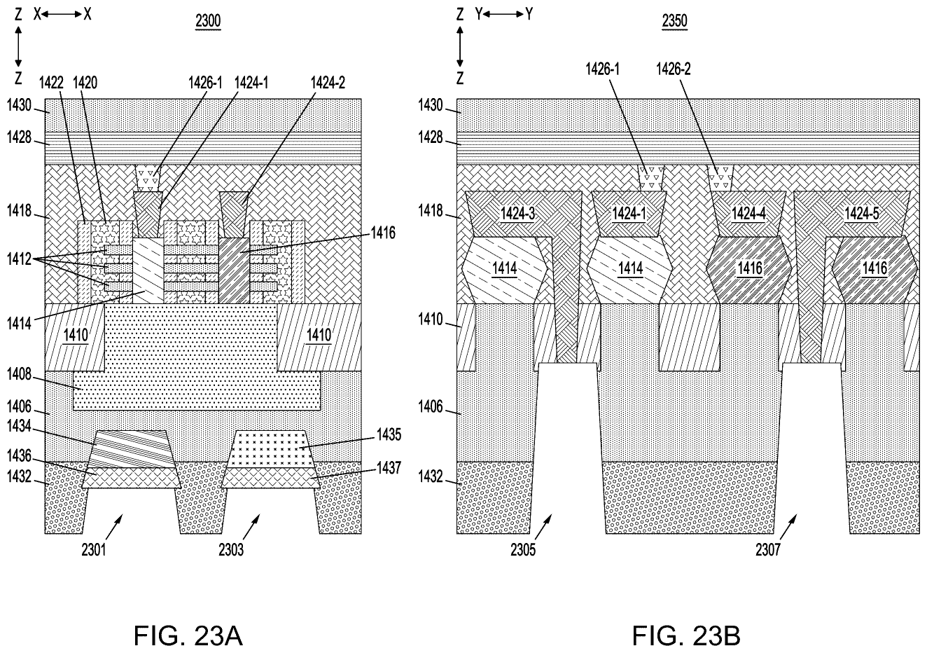

FIGS. 23A and 23B show first and second cross-sectional views 2300 and 2350, respectively, of the structure of FIGS. 22A and 22B following deposition of additional material for the backside ILD layer 1432, and following patterning of openings 2301, 2303, 2305 and 2307 in the backside ILD layer 1432 and the well region 1406 for a backside metal level (M1). The opening 2301 exposes the backside contact 536, the opening 2303 exposes the backside contacts 1437, the opening 2305 exposes the MOL contact 1424-3, and the opening 2307 exposes the MOL contact 1425-5.

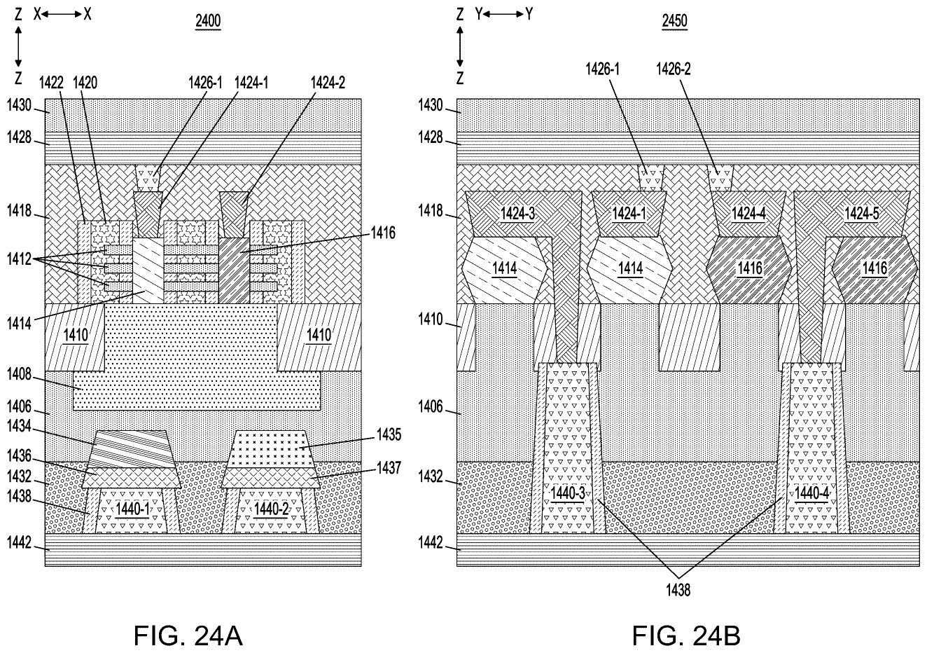

FIGS. 24A and 24B show first and second cross-sectional views 2400 and 2450, respectively, of the structure of FIGS. 23A and 23B following formation of spacers 1438, backside metallization layers 1440-1, 1440-2, 1440-3 and 1440-4 (collectively, backside metallization layers 1440), and backside interconnects 1442. The spacers 1438, the backside metallization layers 1440 and the backside interconnects 1442 may be formed of similar materials, and with similar sizing and processing as that described above with respect to the spacers 538, the backside metallization layers 540 and the backside interconnects 542, respectively.

According to an aspect of the invention, a semiconductor structure includes a first set of one or more interconnects at a first side of the semiconductor structure, a second set of one or more interconnects at a second side of the semiconductor structure opposite the first side of the semiconductor structure, and a vertical SCR having an anode (A) junction, a cathode (C) junction, a first gate (G1) junction and a second gate (G2) junction. The anode (A) junction and the first gate (G1) junction of the vertical SCR are wired to the first set of one or more interconnects at the first side of the semiconductor structure. The cathode (C) junction of the vertical SCR is wired to the second set of one or more interconnects at the second side of the semiconductor structure.

In embodiments, the cathode (C) junction of the vertical SCR is disposed vertically underneath and at least partially overlapping at least one of the anode (A) junction and the first gate (G1) junction.

In embodiments, the second gate (G2) junction of the vertical SCR is wired to first set of one or more interconnects at the first side of the semiconductor structure.

In embodiments, the second gate (G2) junction of the vertical SCR is wired to the second set of one or more interconnects at the second side of the semiconductor structure. Each of the cathode (C) junction and the second gate (G2) junction of the vertical SCR may be disposed vertically underneath and at least partially overlapping at least one of the anode (A) junction and the first gate (G1) junction.

In embodiments, the anode (A) junction of the vertical SCR comprises a first contact connected to a first epitaxial layer proximate the first side of the semiconductor structure, the first epitaxial layer having a first doping. The first epitaxial layer may be a source/drain region for a nanosheet transistor device. The cathode (C) junction of the vertical SCR may include a second contact connected to a second epitaxial layer proximate the second side of the semiconductor structure, the second epitaxial layer having a second doping. The first gate (G1) junction of the vertical SCR may include a third contact connected to a third epitaxial layer proximate the first side of the semiconductor structure, the third epitaxial layer having the second doping. The third epitaxial layer may be a source/drain region for a nanosheet transistor device. The second gate (G2) junction of the vertical SCR may include a fourth contact connected to a fourth epitaxial layer proximate the first side of the semiconductor structure, the fourth epitaxial layer having the first doping. The fourth epitaxial layer may be a source/drain region for a nanosheet transistor device. The second gate (G2) junction of the vertical SCR may include a fourth contact connected to a fourth epitaxial layer proximate the second side of the semiconductor structure, the fourth epitaxial layer having the first doping.

According to an aspect of the invention, a semiconductor structure includes BEOL interconnects at a frontside of the semiconductor structure, a BSPDN at a backside of the semiconductor structure, and a vertical SCR having (i) a first set of one or more junctions wired to the BEOL interconnects at the frontside of the semiconductor structure and (ii) a second set of one or more junctions wired to the BSPDN at the backside of the semiconductor structure.

In embodiments, the first set of one or more junctions includes an anode (A) junction, a first gate (G1) junction and a second gate (G2) junction of the vertical SCR, and the second set of one or more nodes includes a cathode (C) junction of the vertical SCR.

In embodiments, the first set of one or more junctions includes an anode (A) junction and a first gate (G1) junction of the vertical SCR and the second set of one or more nodes includes a cathode (C) junction and a second gate (G2) junction of the vertical SCR.

In embodiments, the first set of one or more junctions are wired between source/drain regions of nanosheet transistor devices and the BEOL interconnects at the frontside of the semiconductor structure, and the second set of one or more junctions are wired between backside epitaxial layers and the BSPDN at the backside of the semiconductor structure.

According to an aspect of the invention, an integrated circuit includes a semiconductor structure including a first set of one or more interconnects at a first side of the semiconductor structure, a second set of one or more interconnects at a second side of the semiconductor structure opposite the first side of the semiconductor structure, and a vertical SCR having an anode (A) junction, a cathode (C) junction, a first gate (G1) junction and a second gate (G2) junction. The anode (A) junction and the first gate (G1) junction of the vertical SCR are wired to the first set of one or more interconnects at the first side of the semiconductor structure. The cathode (C) junction of the vertical SCR is wired to the second set of one or more interconnects at the second side of the semiconductor structure.

In embodiments, the second gate (G2) junction of the vertical SCR is wired to first set of one or more interconnects at the first side of the semiconductor structure.

In embodiments, the second gate (G2) junction of the vertical SCR is wired to the second set of one or more interconnects at the second side of the semiconductor structure.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, complementary metal-oxide-semiconductor (CMOS) transistors, metal-oxide-semiconductor field-effect transistors (MOSFETs), and/or FinFETs. By way of non-limiting example, the semiconductor devices can include, but are not limited to CMOS, MOSFET, and FinFET devices, and/or semiconductor devices that use CMOS, MOSFET, and/or FinFET technology.

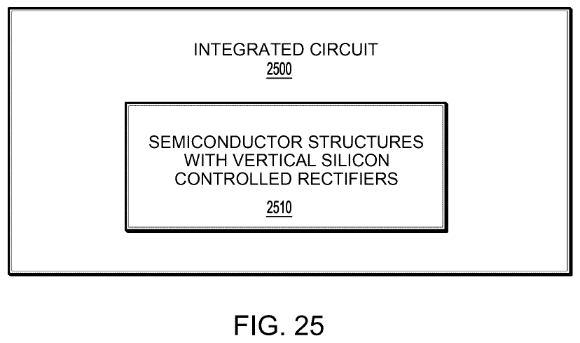

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor. FIG. 25 shows an example integrated circuit 2500 which includes one or more semiconductor structures 2510 with vertical silicon controlled rectifiers.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a first set of one or more interconnects at a first side of the semiconductor structure;
a second set of one or more interconnects at a second side of the semiconductor structure opposite the first side of the semiconductor structure; and
a vertical silicon controlled rectifier having an anode junction, a cathode junction, a first gate junction and a second gate junction;
wherein the anode junction and the first gate junction of the vertical silicon controlled rectifier are wired to the first set of one or more interconnects at the first side of the semiconductor structure; and
wherein the cathode junction of the vertical silicon controlled rectifier is wired to the second set of one or more interconnects at the second side of the semiconductor structure.

2. The semiconductor structure of claim 1, wherein the cathode junction of the vertical silicon controlled rectifier is disposed vertically underneath and at least partially overlapping at least one of the anode junction and the first gate junction.

3. The semiconductor structure of claim 1, wherein the second gate junction of the vertical silicon controlled rectifier is wired to first set of one or more interconnects at the first side of the semiconductor structure.

4. The semiconductor structure of claim 1, wherein the second gate junction of the vertical silicon controlled rectifier is wired to the second set of one or more interconnects at the second side of the semiconductor structure.

5. The semiconductor structure of claim 4, wherein each of the cathode junction and the second gate junction of the vertical silicon controlled rectifier is disposed vertically underneath and at least partially overlapping at least one of the anode junction and the first gate junction.

6. The semiconductor structure of claim 1, wherein the anode junction of the vertical silicon controlled rectifier comprises a first contact connected to a first epitaxial layer proximate the first side of the semiconductor structure, the first epitaxial layer having a first doping.

7. The semiconductor structure of claim 6, wherein the first epitaxial layer comprises a source/drain region for a nanosheet transistor device.

8. The semiconductor structure of claim 6, wherein the cathode junction of the vertical silicon controlled rectifier comprises a second contact connected to a second epitaxial layer proximate the second side of the semiconductor structure, the second epitaxial layer having a second doping.

9. The semiconductor structure of claim 8, wherein the first gate junction of the vertical silicon controlled rectifier comprises a third contact connected to a third epitaxial layer proximate the first side of the semiconductor structure, the third epitaxial layer having the second doping.

10. The semiconductor structure of claim 9, wherein the third epitaxial layer comprises a source/drain region for a nanosheet transistor device.

11. The semiconductor structure of claim 9, wherein the second gate junction of the vertical silicon controlled rectifier comprises a fourth contact connected to a fourth epitaxial layer proximate the first side of the semiconductor structure, the fourth epitaxial layer having the first doping.

12. The semiconductor structure of claim 11, wherein the fourth epitaxial layer comprises a source/drain region for a nanosheet transistor device.

13. The semiconductor structure of claim 9, wherein the second gate junction of the vertical silicon controlled rectifier comprises a fourth contact connected to a fourth epitaxial layer proximate the second side of the semiconductor structure, the fourth epitaxial layer having the first doping.

14. A semiconductor structure comprising:
back-end-of-line interconnects at a frontside of the semiconductor structure;
a backside power delivery network at a backside of the semiconductor structure; and
a vertical silicon controlled rectifier having (i) a first set of one or more junctions wired to the back-end-of-line interconnects at the frontside of the semiconductor structure and (ii) a second set of one or more junctions wired to the backside power delivery network at the backside of the semiconductor structure.

15. The semiconductor structure of claim 14, wherein:
the first set of one or more junctions comprises an anode junction, a first gate junction and a second gate junction of the vertical silicon controlled rectifier; and
the second set of one or more junctions comprises a cathode junction of the vertical silicon controlled rectifier.

16. The semiconductor structure of claim 14, wherein:
the first set of one or more junctions comprises an anode junction and a first gate junction of the vertical silicon controlled rectifier; and
the second set of one or more nodes comprises a cathode junction and a second gate junction of the vertical silicon controlled rectifier.

17. The semiconductor structure of claim 14, wherein:
the first set of one or more junctions are wired between source/drain regions of nanosheet transistor devices and the back-end-of-line interconnects at the frontside of the semiconductor structure; and
the second set of one or more junctions are wired between backside epitaxial layers and the backside power delivery network at the backside of the semiconductor structure.

18. An integrated circuit comprising:
a semiconductor structure comprising:
a first set of one or more interconnects at a first side of the semiconductor structure;
a second set of one or more interconnects at a second side of the semiconductor structure opposite the first side of the semiconductor structure; and
a vertical silicon controlled rectifier having an anode junction, a cathode junction, a first gate junction and a second gate junction;
wherein the anode junction and the first gate junction of the vertical silicon controlled rectifier are wired to the first set of one or more interconnects at the first side of the semiconductor structure; and
wherein the cathode junction of the vertical silicon controlled rectifier is wired to the second set of one or more interconnects at the second side of the semiconductor structure.

19. The integrated circuit of claim 18, wherein the second gate junction of the vertical silicon controlled rectifier is wired to first set of one or more interconnects at the first side of the semiconductor structure.

20. The integrated circuit of claim 18, wherein the second gate junction of the vertical silicon controlled rectifier is wired to the second set of one or more interconnects at the second side of the semiconductor structure.
